(19) United States
(12) Patent Application Publication
(10) Pub. No.: US 2024/0413223 A1
(43) Pub. Date: Dec. 12, 2024

(54) SEMICONDUCTOR STRUCTURE WITH REDUCED LEAKAGE CURRENT AND METHOD FOR MANUFACTURING THE SAME

(71) Applicant: TAIWAN SEMICONDUCTOR MANUFACTURING COMPANY, LTD., Hsinchu (TW)

(72) Inventors: Chung-En TSAI, Hsinchu (TW); Chih-Yu MA, Hsinchu (TW); Cheng-Han LEE, Hsinchu (TW); Shih-Chieh CHANG, Hsinchu (TW); Sheng-Syun WONG, Hsinchu (TW)

(73) Assignee: TAIWAN SEMICONDUCTOR MANUFACTURING COMPANY, LTD., Hsinchu (TW)

(21) Appl. No.: 18/331,745

(22) Filed: Jun. 8, 2023

(51) Int. Cl. H01L 29/66; H01L 21/8238; H01L 27/092; H01L 29/06; H01L 29/08; H01L 29/423; H01L 29/775

(52) U.S. Cl. CPC H01L 29/66439; H01L 21/823807; H01L 21/823814; H01L 27/092; H01L 29/0673; H01L 29/0847; H01L 29/42392; H01L 29/66545; H01L 29/66553; H01L 29/775

(57) ABSTRACT

A method for manufacturing a semiconductor structure includes: forming a channel portion on a fin portion; forming two source/drain portions on the fin portion and at two opposite sides of the channel portion, in which each of the two source/drain portions includes a first semiconductor material that is doped with dopant impurities; and forming two bottom portions each of which is disposed between the fin portion and a corresponding one of the two source/drain portions, in which each of the two bottom portions includes a second semiconductor material that is different from the first semiconductor material and that is capable of trapping the dopant impurities when the dopant impurities in the first semiconductor material diffuse toward the fin portion.

### BACKGROUND

Transistors are key active components in modern integrated circuits (ICs). With the rapid development of semiconductor technology, the critical dimension (CD) of transistors keeps shrinking, the configuration of gate structure continues to evolve, and various three-dimensional (3D) transistor structures have been developed, making it possible to increase the number of transistors per unit area. With the size miniaturization of the transistors, current leakage is one important factor that influences energy consumption performance of consumer electronic products. Currently, advanced node 3D ICs with reduced current leakage are in continuous development with the aim of achieving a better Power-Performance-Area (PPA).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIG. 2 is a flow diagram illustrating a step of the method depicted in FIG. 1 in accordance with some embodiments.

FIGS. 3 to 9 illustrate schematic views of intermediate stages of the method depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

With the rapid development of semiconductor technology, the structural design of semiconductor devices has evolved from bulk silicon-based devices, silicon-on-insulator-based (SOI-based) devices, Fin-type field effect transistors (FinFETs), gate-all-around field effect transistors (GAAFETs), nanosheet GAAFETs, nanowire GAAFETs, forksheet-based devices, to complementary field effect transistors (CFET, a stack of FETs). In advanced technology nodes, source/drain portions are usually epitaxially grown on un-doped silicon with high crystallinity and purity to reduce defects in the source/drain portions (e.g., lattice defect, voids, and so on). In addition, the high purity un-doped silicon provides a function of electrical isolation (or insulation) between the source/drain portions and a substrate. However, in 2 nm technology node or below, since a distance between the source/drain portions and a substrate is small, the high purity un-doped silicon is unable to sufficiently isolate the source/drain portions from the substrate, resulting in an increased leakage current. In some embodiments, the un-doped silicon may be replaced with a dielectric material or an electrically insulating material to reduce the leakage current. However, formation of the source/drain portions on the dielectric material has a slower growth rate, and the source/drain portions formed on the dielectric material has a poorer quality. Therefore, the present disclosure is directed to a semiconductor structure having a suppressed leakage current, and including source/drain portions with less defects. The semiconductor structure may be applied to nanosheet GAAFETs, nanowire GAAFETs, complementary FETs, fork-sheet FETs, structures including sources and/or drains, memory cells including the abovementioned FETs, inverters including the abovementioned FETs, or other suitable devices or applications including the abovementioned FETs.

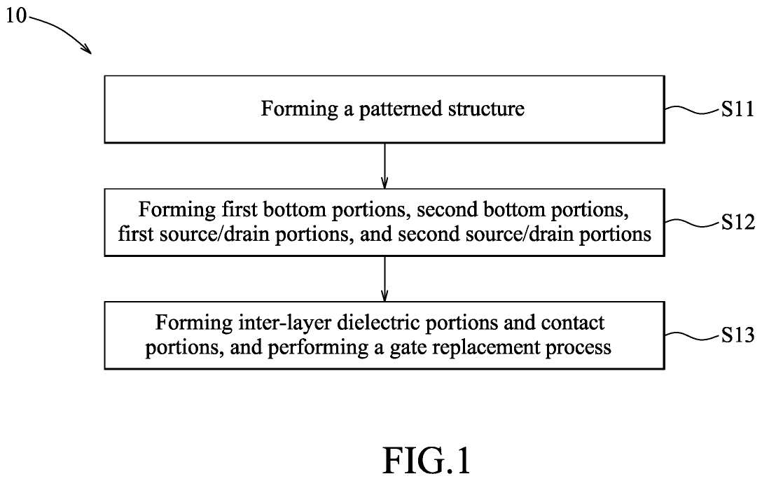

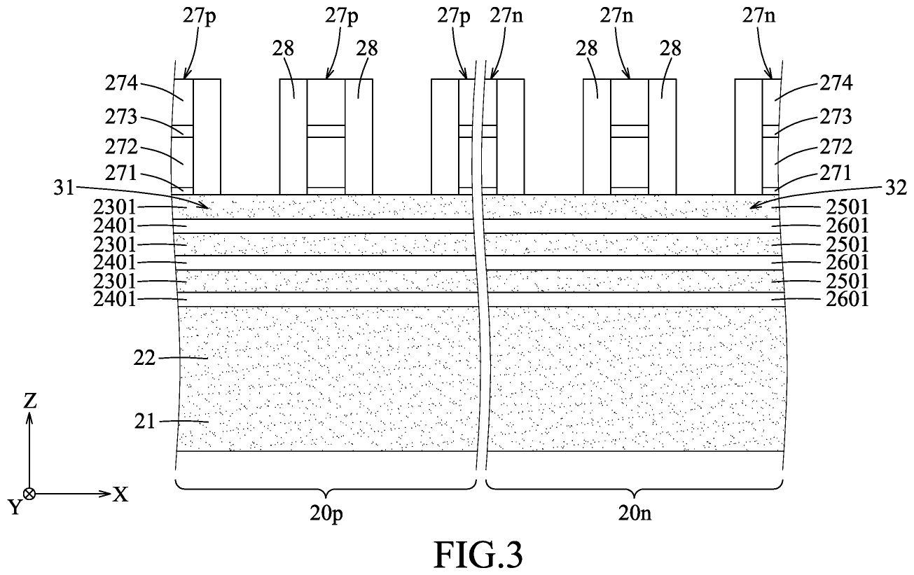

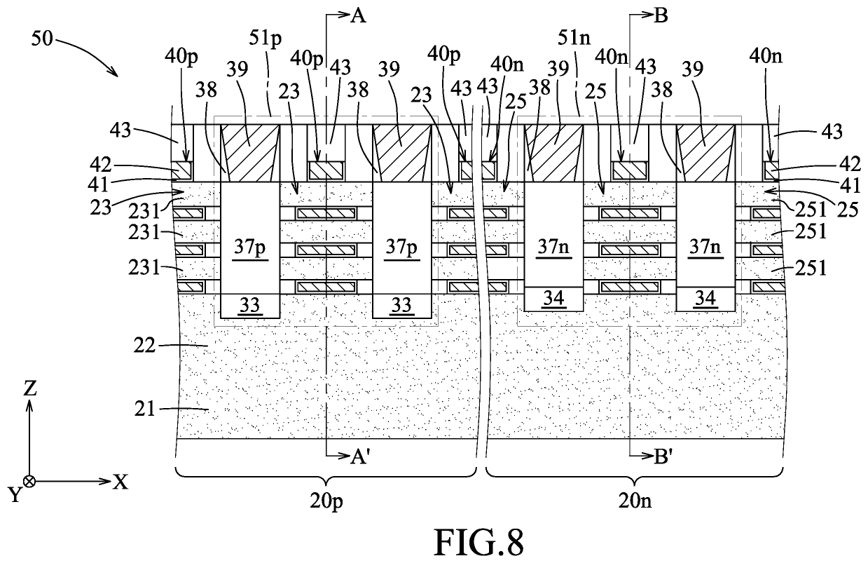

FIG. 1 is flow diagram illustrating a method 10 for manufacturing a semiconductor structure (for example, a semiconductor structure 50 shown in FIG. 8) in accordance with some embodiments. FIGS. 3 to 9 illustrate schematic views of intermediate stages of the method 10 in accordance with some embodiments. Some repeating structures are omitted in FIGS. 3 to 9 for the sake of brevity.

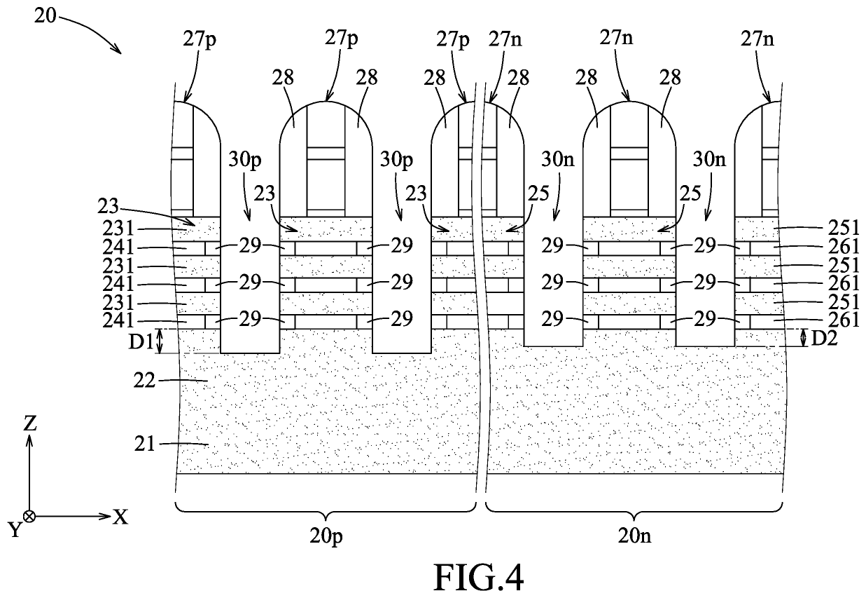

Referring to FIG. 1 and the example illustrated in FIG. 4, the method 10 begins at step S11, where a patterned structure 20 is formed. It should be noted that although the method 10 is exemplified by a method for manufacturing a GAA structure including a plurality of GAAFETs (for example, a first device 51p and a second device 51n, as shown in FIG. 8), the method 10 may also be used for manufacturing other suitable structures, such as fork-sheet FETs, complementary FET (CFET) including at least two GAAFETs stacked on each other in a Z direction. In some embodiments, the first device 51p and the second device 51n may be referred to as a p-FET and an n-FET, respectively. It is noted that although one n-FET and one p-FET are shown in FIG. 8, the number of n-FETs and the number of p-FETs may vary according to practical requirements.

In some embodiments, the patterned structure 20 includes a substrate 21, a plurality of fin portions 22, a plurality of first channel portions 23, a plurality of second channel portions 25, and a plurality of dummy gate portions 27p, 27n.

In some embodiments, the substrate 21 may be made of elemental semiconductor materials, such as crystalline silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. In addition, the substrate 21 may be a bulk silicon substrate, a silicon-on-insulator (SOI) substrate, or a germanium-on-insulator (GOI) substrate. Other materials or configurations suitable for the substrate 21 are within the contemplated scope of the present disclosure. In some embodiments, the substrate 21 includes a p-region 20p designed for forming the p-FET 51p thereabove and an n-region 20n designed for forming the n-FET 51n thereabove.

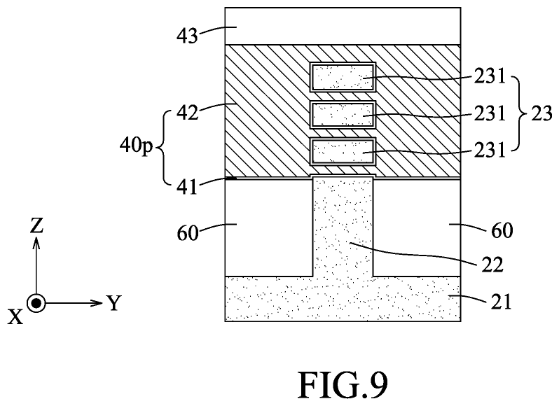

The fin portions 22 are disposed on the p-region 20p and the n-region 20n of the substrate 21 and spaced apart from each other in a Y direction transverse to the Z direction by a corresponding one of isolation regions 60 (see FIG. 9; e.g., a shallow trench isolation). In some embodiments, one of the fin portions 22 that is formed on the p-region 20p of the substrate 21 may have a p-region for forming the p-FET 51p thereon subsequently, and another one of the fin portions 22 that is formed on the n-region 20n of the substrate 21 may have an n-region for forming the n-FET 51n thereon subsequently. In some embodiments, the p-FET 51p and the n-FET 51n may be formed on the same one of the fin portions 22. In this case, such fin portion 22 is formed across the p-region 20p and the n-region 20n of the substrate 21, and may have a p-region and an n-region that correspond in position, respectively, to the p-region 20p and the n-region 20n of the substrate 21, and that are thus respectively denoted by 20p and 20n for the sake of brevity, and the p-FET 51p and the n-FET 51n are respectively formed on the p-region 20p and the n-region 20n of the fin portion 22. In the following description, the fin portion 22 will generally be described in singular form for the sake of brevity. Unless explicitly indicated to the contrary, describing a feature in singular form encompasses the practice of one or a plurality of such features.

The fin portion 22 may include a semiconductor material, such as the examples of the semiconductor material of the substrate 21 given in the preceding paragraph. In some embodiments, the fin portion 22 and the substrate 21 may be made of the same semiconductor material.

In some embodiments, the semiconductor material of the substrate 21 and the fin portion 22 are un-doped. In some embodiments, for reducing substrate leakage current (i.e., leakage current flowing through the substrate 21), the semiconductor material of the p-region 20p of the substrate 21 and/or the fin portion 22 may be doped with n-type impurities to have an n-well, and the semiconductor material of the n-region 20n of the substrate 21 and/or the fin portion 22 may be doped with p-type impurities to have a p-well. In some embodiments, the n-well may include a group IV semiconductor element (e.g., silicon, germanium or silicon germanium) doped with a group V element (e.g., nitrogen, phosphorus, arsenic, antimony, or combinations thereof), and an atomic percentage of the group V element in the group IV semiconductor element ranges from about 0.00000001% to about 0.0000001%. In some embodiments, the p-well may include a group IV semiconductor element (e.g., silicon, germanium or silicon germanium) doped with a group III element (e.g., boron, aluminum, gallium, indium, or combinations thereof), and an atomic percentage of the group III element in the group IV semiconductor element ranges from about 0.00000001% to about 0.0000001%.

The first channel portions 23 are disposed on the p-region 20p of the fin portion 22 and are spaced apart from each other in an X direction transverse to the Y and Z directions. The second channel portions 25 are disposed on the n-region 20n of the fin portion 22 and are spaced apart from each other in the X direction. In some embodiments, the X, Y and Z directions are perpendicular to one another. As shown in FIG. 4, the number of the first channel portions 23 is three and the number of the second channel portions 25 is three, but other numbers are also within the scope of this disclosure. In some embodiments, each of the first channel portions 23 and the second channel portions 25 may include a semiconductor material, such as the examples of the semiconductor material of the substrate 21 given in the preceding paragraph. In some embodiments, the semiconductor material of the first channel portions 23 may be the same as or different from that of the p-region 20p of the fin portion 22. In some embodiments, the semiconductor material of the second channel portions 25 may be the same as or different from that of the n-region 20n of the fin portion 22. In some embodiments, the semiconductor material of the first channel portions 23 may be the same as or different from that of the second channel portions 25.

The dummy gate portions 27p, 27n are each elongated in the Y direction and are spaced apart from each other in the X direction. As shown in FIG. 4, three of the dummy gate portions are denoted by 27p and are respectively disposed over the first channel portions 23. The other three of the dummy gate portions are denoted by 27n and are respectively disposed over the second channel portions 25. In some embodiments, each of the dummy gate portions 27p, 27n includes a dummy gate dielectric layer 271, a dummy gate electrode 272, a polish stop layer 273, and a hard mask layer 274 sequentially disposed on one another in a direction away from the channel portions 23, 25 (see FIG. 4). In some embodiments, the hard mask layer 274 may include silicon nitride, silicon oxide, silicon oxynitride, or combinations thereof, the polish stop layer 273 may include silicon nitride, silicon oxide, silicon oxynitride, or combinations thereof, the dummy gate electrode 272 may include polycrystalline silicon, single crystalline silicon, amorphous silicon, or combinations thereof, and the dummy gate dielectric layer 271 may include silicon oxide, silicon nitride, silicon oxynitride, high dielectric constant (k) materials, or combinations thereof. Other suitable materials for the dummy gate portions 27p, 27n are within the contemplated scope of the present disclosure.

In some embodiments, the patterned structure further includes multiple pairs of gate spacers 28, where the two gate spacers 28 of each pair are disposed at two opposite sides of a corresponding one of the dummy gate portions 27p, 27n in the X direction. In some embodiments, each of the gate spacers 28 may be formed as a single-layer structure or a multi-layered structure, and include a dielectric material. In some embodiments, the gate spacers 28 may include a nitride-based dielectric material, such as silicon nitride, silicon oxynitride, silicon carbon nitride, silicon oxycarbonnitride, but not limited thereto. Other dielectric materials suitable for the gate spacers 28 are within the contemplated scope of the present disclosure.

In some embodiments, in order to form the p-FET 51p and the n-FET 51n shown in FIG. 8, each of the first channel portions 23 may include a plurality of first channel layers 231 spaced apart from each other in the Z direction, and the patterned structure 20 further includes a plurality of first sacrificial layers 241 disposed to alternate with the first channel layers 231 of each of the first channel portions 23. In some embodiments, an uppermost one of the first channel layers 231 is disposed over an uppermost one of the first sacrificial layers 241. In some embodiments, a bottommost one of the first channel layers 231 is separated from the p-region 20p of the fin portion 22 by a bottommost one of the first sacrificial layers 241.

In some embodiments, each of the second channel portions 25 may include a plurality of second channel layers 251 spaced apart from each other in the Z direction, and the patterned structure 20 further includes a plurality of second sacrificial layers 261 disposed to alternate with the second channel layers 251 of each of the second channel portions 25. In some embodiments, an uppermost one of the second channel layers 251 is disposed over an uppermost one of the second sacrificial layers 261. In some embodiments, a bottommost one of the second channel layers 251 is separated from the n-region 20n of the fin portion 22 by a bottommost one of the second sacrificial layers 261.

In some embodiments, as shown in FIG. 4, the number of the first channel layers 231 in each of the first channel portions 23 and the number of the second channel layers 251 in each of the second channel portions 25 are each three, but other numbers are also within the scope of this disclosure. In some embodiments not shown herein, the number of the first channel layers 231 in each of the first channel portions 23 may be two, four or five, and the number of the second channel layers 251 in each of the second channel portions 25 may be two, four or five, according to practical requirements. It is noted that the number of the first channel layers 231 in each of the first channel portions 23 and the number of the second channel layers 251 in each of the second channel portions 25 may be the same as or different from each other. The number of the first sacrificial layers 241 and the number of the second sacrificial layers 261 are determined based on the number of the first channel layers 231 and the number of the second channel layers 251, respectively.

In some embodiments, each of the first channel layers 231 may have a thickness ranging from about 3 nm to about 12 nm. In some embodiments, each of the first sacrificial layers 241 may have a thickness ranging from about 5 nm to about 12 nm. In some embodiments, each of the second channel layers 251 may have a thickness ranging from about 3 nm to about 12 nm. In some embodiments, each of the second sacrificial layers 261 may have a thickness ranging from about 5 nm to about 12 nm. In some embodiments, the thickness of the first channel layers 231 may be the same as or different from that of the second channel layers 251. In some embodiments, the thickness of the first sacrificial layers 241 may be the same as or different from that of the second sacrificial layers 261.

In some embodiments, each of the first sacrificial layers 241 and the second sacrificial layers 261 may include a semiconductor material different from that of the first channel layers 231 and the second channel layers 251, such that the sacrificial layers 241, 261 may have an etching selectivity different from that of the channel layers 231, 251. Thus, by selecting a suitable etchant, the sacrificial layers 241, 261 can be selectively removed in subsequent processes without removing the channel layers 231, 251. Possible semiconductor materials suitable for the sacrificial layers 241, 261 are similar to those for the channel layers 231, 251, and thus the details thereof are omitted for the sake of brevity. In some embodiments, the channel layers 231, 251 are made of silicon, and the the sacrificial layers 241, 261 are made of silicon germanium.

In some embodiments, the patterned structure 20 further includes multiple pairs of inner spacers 29, with the inner spacers 29 of each pair being disposed at two opposite sides of a corresponding one of the sacrificial layers 241, 261 in the X direction. In some embodiments, the inner spacers 29 may include a low-k dielectric material, such as silicon oxide, silicon nitride, silicon oxynitride, silicon carbonitride, silicon oxycarbide, silicon oxycarbonitride, silicon carbide, etc. Other low-k dielectric materials suitable for the inner spacers 29 are within the contemplated scope of the present disclosure.

In some embodiments not shown herein, when the p-FET 51p and the n-FET 51n are configured as a FinFET structure, the channel layers 231, 251 in each of the channel portions 23, 25 are not separated by the sacrificial layers 241, 261, and are formed as a single channel.

In some embodiments, formation of the patterned structure 20 shown in FIG. 4 may include sub-steps of: (i) forming a first laminated structure 31 on the p-region 20p of the fin portion 22, the first laminated structure 31 including a plurality of first sub-layers 2301 that are for forming the first channel layers 231 and a plurality of second sub-layers 2401 that are for forming the first sacrificial layers 241 and that are disposed to alternate with the first sub-layers 2301, as shown in FIG. 3; (ii) forming a second laminated structure 32 on the n-region 20n of the fin portion 22, the second laminated structure 32 including a plurality of third sub-layers 2501 that are for forming the second channel layers 251 and a plurality of fourth sub-layers 2601 that are for forming the second sacrificial layers 261 and that are disposed to alternate with the third sub-layers 2501, as shown in FIG. 3; (iii) forming the dummy gate portions 27p over the first laminated structure 31 and forming the dummy gate portions 27n over the second laminated structure 32, as shown in FIG. 3; (iv) forming the pairs of gate spacers 28, with the gate spacers 28 of each pair being disposed at two opposite sides of a corresponding one of the dummy gate portions 27p, 27n, as shown in FIG. 3; (v) patterning the first and second laminated structures 31, 32 using the dummy gate portions 27p, 27n and the gate spacers 28 as a hard mask to form a plurality of source/drain recesses 30p, 30n, such that the first sub-layers 2301 are patterned into the first channel layers 231, such that the second sub-layers 2401 are patterned into a plurality of first sacrificial films (not shown), which are disposed to alternate with the first channel layers 231, such that the third sub-layers 2501 are patterned into the second channel layers 251, and such that the fourth sub-layers 2601 are patterned into a plurality of second sacrificial films (not shown), which are disposed to alternate with the second channel layers 251; (vi) recessing the first and second sacrificial films through the source/drain recesses 30p, 30n to form multiple pairs of lateral recesses (not shown), wherein the lateral recesses in each pair are spaced apart from each other in the X direction, such that the first sacrificial films are formed into the first sacrificial layers 241, and the second sacrificial films are formed into the second sacrificial layers 261; and (vii) forming the pairs of inner spacers 29 to fill the pairs of lateral recesses, respectively. Other suitable process flows for forming the patterned structure 20 are within the contemplated scope of the present disclosure. One or more deposition processes (such as chemical vapor deposition (CVD), atomic layer deposition (ALD), physical vapor deposition (PVD), or other suitable deposition processes), one or more photolithography processes (such as coating a photoresist, exposing the photoresist through a photomask, developing the photoresist, etching through the developed photoresist, stripping or ashing the photoresist, and/or other suitable processes), one or more etching processes for patterning (such as dry etching, wet etching, other suitable techniques, or combinations thereof), and/or one or more planarization processes (such as chemical mechanical planarization (CMP), or other suitable planarization processes) may be used in step S11, but this disclosure is not limited to such. In some embodiments, sub-step (ii) may be performed before or after sub-step (i). In some other embodiments, sub-steps (i) and (ii) may be performed simultaneously.

In some embodiments, each of the source/drain recesses 30p, 30n is recessed into the fin portion 22 so as to ensure that a bottommost one of the second sub-layers 2401 and a bottommost one of the fourth sub-layers 2601 are patterned in sub-step (v). In the illustrated example, two of the source/drain recesses, which are denoted by 30p, are recessed into the p-region 20p of the fin portion 22, and two of the source/drain recesses, which are denoted by 30n, are recessed into the n-region 20n of the fin portion 22. In some embodiments, each of the source/drain recesses 30p may recess into the p-region 20p of the fin portion 22 by a first depth D1 that is measured from a lower surface of a bottommost one of the first sacrificial layers 241 and that is in a range from about 0.5 nm to about 8 nm. In some embodiments, each of the source/drain recesses 30n may recess into the n-region 20n of the fin portion 22 by a second depth D2 that is measured from a lower surface of a bottommost one of the second sacrificial layers 261 and that is in a range from about 0.5 nm to about 8 nm. In some embodiments, the first depth D1 is greater than the second depth D2, as shown in FIG. 4. In some other embodiments not shown herein, the first depth D1 is less than the second depth D2. In some yet other embodiments not shown herein, the first depth D1 is substantially equal to the second depth D2.

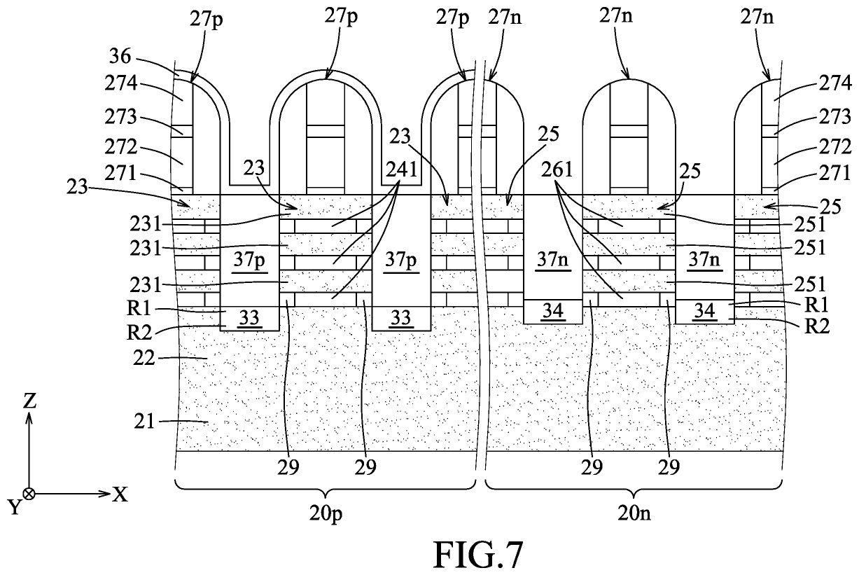

Referring to FIG. 1 and the example illustrated in FIG. 7, the method 10 proceeds to step S12, where a plurality of first bottom portions 33, a plurality of first source/drain portions 37p, a plurality of second bottom portions 34, and a plurality of second source/drain portions 37n are formed. FIG. 7 is similar to FIG. 4, but illustrating the structure after step S12.

In some embodiments, each of the first source/drain portions 37p is formed on the p-region 20p of the fin portion 22. Two adjacent ones of the first source/drain portions 37p are disposed at two opposite sides of a corresponding one of the first channel portions 23 in the X direction, respectively, such that each of the first channel layers 231 in the corresponding one of the first channel portions 23 extends between the two adjacent ones of the first source/drain portions 37p. In some embodiments, each of the second source/drain portions 37n is formed on the n-region 20n of the fin portion 22. Two adjacent ones of the second source/drain portions 37n are disposed at two opposite sides of a corresponding one of the second channel portions 25 in the X direction, respectively, such that each of the second channel layers 251 in the corresponding one of the second channel portions 25 extends between the two adjacent ones of the second source/drain portions 37n.

In some embodiments, each of the first source/drain portions 37p includes a p-type semiconductor material that is doped with a p-type dopant (which may also be referred to as p-type dopant impurities), and each of the second source/drain portions 37n includes an n-type semiconductor material that is doped with an n-type dopant (which may also be referred to as n-type dopant impurities). In some embodiments, for example, the p-type semiconductor material may include a group IV element and a group III element serving as the p-type dopant. The group IV element may include silicon, germanium, or a combination thereof, and the group III element may include boron, aluminum, indium, or combinations thereof. In some embodiments, the p-type dopant in the p-type semiconductor material may be in a dopant concentration ranging from about 1E19 atoms/cm³ to about 1E21 atoms/cm³. In other words, an atomic percentage of the p-type dopant in the p-type semiconductor material ranges from about 0.02% to about 10%. In some embodiments, for example, the n-type semiconductor material may include the group IV element (such as the examples mentioned above) and a group V element serving as the n-type dopant. The group V element may include nitrogen, phosphorous, arsenic, or combinations thereof. In some embodiments, the n-type dopant in the n-type semiconductor material may be in a dopant concentration ranging from about 1E19atoms/cm³ to about 1E21 atoms/cm³. In other words, an atomic percentage of the n-type dopant in the n-type semiconductor material ranges from about 0.02% to about 10%. It is noted that source/drain region(s) (e.g., the source/drain portions 37p, 37n) may refer to a source or a drain, individually or collectively, dependent upon the context.

In some embodiments, each of the first bottom portions 33 is formed beneath a corresponding one of the first source/drain portions 37p so as to be located between the p-region 20p of the fin portion 22 and the corresponding one of the first source/drain portions 37p, and is capable of trapping the p-type dopant when the p-type dopant in the corresponding one of the first source/drain portions 37p diffuses toward the fin portion 22. In some embodiments, each of the second bottom portions 34 is formed beneath a corresponding one of the second source/drain portions 37n so as to be located between the n-region 20n of the fin portion 22 and the corresponding one of the second source/drain portions 37n, and is capable of trapping the n-type dopant when the n-type dopant in the corresponding one of the second source/drain portions 37n diffuses toward the fin portion 22.

In some embodiments, each of the first and second bottom portions 33, 34 may include a group IV semiconductor material and trapping elements doped in the group IV semiconductor material. In some embodiments, the group IV semiconductor material may include silicon, germanium, or a combination thereof, and the trapping elements may include carbon, antimony, gallium, or combinations thereof. In certain embodiments, each of the first and second bottom portions 33, 34 is made of silicon doped with carbon, antimony, gallium, or combinations thereof. In some embodiments, the trapping elements in each of the first and second bottom portions 33, 34 may be in a dopant concentration ranging from about 1E19 atoms/cm³ to about 1E21 atoms/cm³. In other words, the trapping elements are in an atomic percentage ranging from about 0.02% to about 10% based on total atoms of the group IV semiconductor material and the trapping elements. In some embodiments, the first and second bottom portions 33, 34 are made of the same material.

In some embodiments, the first bottom portions 33, 34 may have a thickness ranging from about 0.5 nm to about 10 nm, and the second bottom portions 33, 34 may have a thickness ranging from about 0.5 nm to about 10 nm. In some embodiments, each of the first bottom portions 33 may have an upper surface at a level higher than that of the lower surface of the bottommost one of the first sacrificial layers 241 by a height ranging from about 0 nm to about 2 nm. In some embodiments, each of the first bottom portions 33 may have a lower surface at a level lower than that of the lower surface of the bottommost one of the first sacrificial layers 241 by a height ranging from about 0.5 nm to about 8 nm. In some embodiments, each of the second bottom portions 34 may have an upper surface at a level higher than that of the lower surface of the bottommost one of the second sacrificial layers 261 by a height ranging from about 0 nm to about 2 nm. In some embodiments, each of the second bottom portions 34 may have a lower surface at a level lower than that of the lower surface of the bottommost one of the second sacrificial layers 261 by a height ranging from about 0.5 nm to about 8 nm.

In some embodiments, the trapping elements may be evenly distributed in each of the first and second bottom portions 33, 34. In some embodiments, the trapping elements in each of the first and second bottom portions 33, 34 may be unevenly distributed. For example, each of the bottom portions 33, 34 may have an upper region R1 and a lower region R2 that are respectively distal from and proximate to the substrate 21. A localized concentration of the trapping elements in each of the bottom portions 33, 34 may be a maximum at the upper region R1, and gradually decreases toward the lower region R2. In some embodiments, the localized concentration of the trapping elements in each of the bottom portions 33, 34 may decrease in a Gaussian-like manner. In some embodiments, the localized concentration of the trapping elements in each of the bottom portions 33, 34 may decrease in a complementary-error-function-like manner.

In some embodiments, the first bottom portions 33 and the second bottom portions 34 mainly serve to respectively capture the p-type dopant diffusing outward from the first source/drain portions 37p and the n-type dopant diffusing outward from the second source/drain portions 37n during subsequent thermal processes, and each of the first and second bottom portions 33, 34 does not serve as a source or a drain of a corresponding one of the p-FET 51p and the n-FET 51n. Therefore, each of the first bottom portions 33 is entirely separated from the first channel layers 231 by a corresponding of the first source/drain portions 37p, and each of the second bottom portions 34 is entirely separated from the second channel layers 251 by a corresponding one of the second source/drain portions 37n. In some embodiments, the upper surface of each of the first bottom portions 33 is at a level lower than that of a lower surface of a bottommost one of the first channel layers 231. In some embodiments, the upper surface of each of the second bottom portions 34 is at a level lower than that of a lower surface of a bottommost one of the second channel layers 251.

In some embodiments, in order to further prevent the p-type dopant from easily diffusing into the fin portion 22, the first source/drain portions 37p may be entirely separated from the p-region 20p of the fin portion 22 by the first bottom portions 33, respectively, so as to enlarge a distance between the p-region 20p of the fin portion 22 and the first source/drain portions 37p. Also, in order to further prevent the n-type dopant from easily diffusing into the fin portion 22, the second source/drain portions 37n may be entirely separated from the n-region 20n of the fin portion 22 by the second bottom portions 34, respectively, so as to enlarge a distance between the n-region 20n of the fin portion 22 and the second source/drain portions 37n. In some embodiments, the two inner spacers 29 in each bottommost pair of the inner spacers 29 located on the p-region 20p of the fin portion 22 may be covered by two corresponding adjacent ones of the first bottom portions 33, respectively. In some embodiments, the two inner spacers 29 in each bottommost pair of the inner spacers 29 located on the n-region 20n of the fin portion 22 may be covered by two corresponding adjacent ones of the second bottom portions 34, respectively.

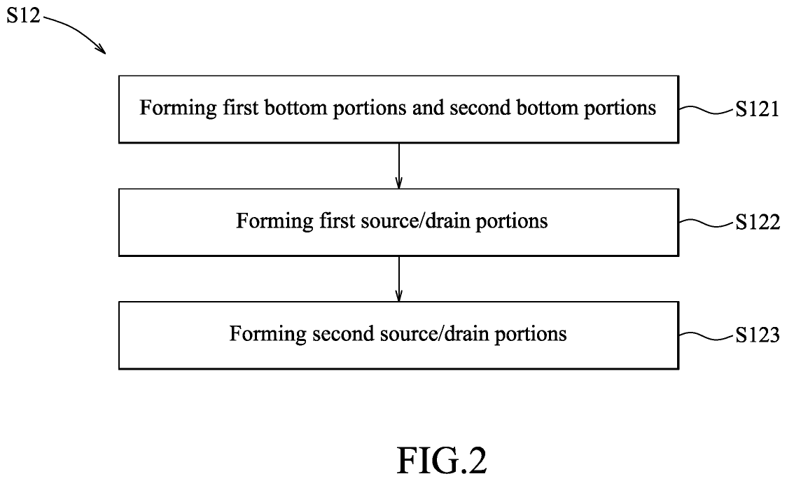

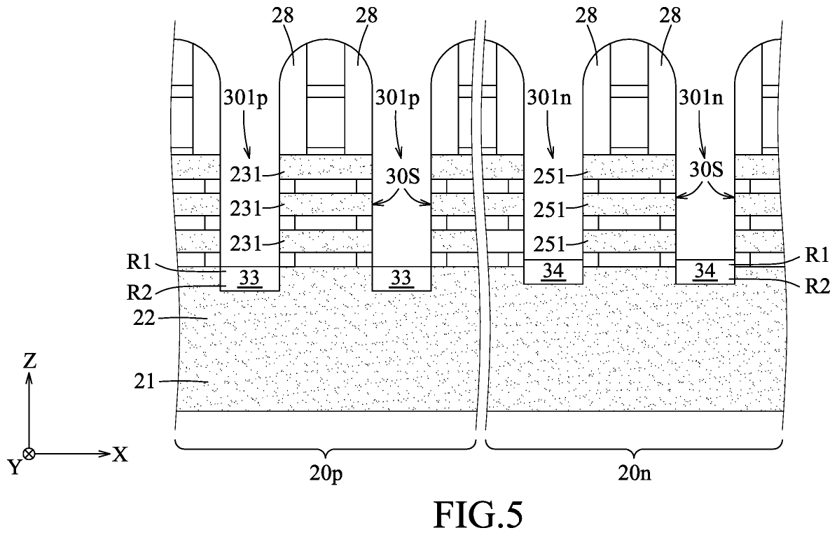

FIG. 2 is a flow diagram illustrating step S12 which may include sub-steps S121 to S123 in accordance with some embodiments. FIGS. 5 to 7 illustrate schematic views of intermediate stages of step S12 in accordance with some embodiments.

FIG. 5 is similar to FIG. 4, but illustrating the structure after sub-step S121. In sub-step S121, the first bottom portions 33 are respectively formed at bottom regions of the source/drain recesses 30p (see FIG. 4) without covering the first channel layers 231, and the second bottom portions 34 are respectively formed at bottom regions of the source/drain recesses 30n (see FIG. 4) without covering the second channel layers 251. In some embodiments, the first and second bottom portions 33, 34 are simultaneously formed by an epitaxial growth process including molecular-beam epitaxy (MBE), an epitaxial deposition/partial etch process, such as a cyclic deposition-etch (CDE) process and/or a selective epitaxial growth (SEG) process, but the disclosure is not limited to such. In some embodiments, a gas mixture is used in the epitaxial growth process for forming the first and second bottom portions 33, 34, and includes a first precursor gas, a second precursor gas and an etching gas. The first precursor gas and the second precursor gas are provided to form the material of the first and second bottom portions 33, 34. In some embodiments, the first precursor gas provides the elements of the group IV semiconductor material, and may include silane (SiH₄, which provides silicon), dichlorosilane (DCS, which provides silicon), disilane (Si₂H₆, which provides silicon), germane (GeH₄, which provides germanium), or combinations thereof, but not limited thereto. In some embodiments, the second precursor gas provides the trapping elements, and may include hydrocarbon (CₓH_{y}, which provides carbon), methyl methane sulfonate (MMS, which provides carbon), trimethylgallium (Ga(CH₃)₃, which provides gallium), triethylgallium (Ga(C₂H₅)₃, which provides gallium), antimony trichloride (SbCl₃, which provides antimony), or combinations thereof, but not limited thereto. The first precursor gas and the second precursor gas may vary according to the material of the first and second bottom portions 33, 34. The etching gas is provided to remove excess portions of the material of the first and second bottom portions 33, 34 that are undesirably formed on an inner surface 30S of each of top regions of the source/drain recesses 30p, 30n and/or on the gate spacers 28. In some embodiments, the etching gas includes hydrogen chloride (HCl), chlorine gas (Cl₂), hydrogen fluoride (HF), hydrogen bromide (HBr), fluorine gas (F₂), or combinations thereof, but not limited thereto. In some embodiments, the gas mixture may further include a carrier gas, such as hydrogen gas (H₂), nitrogen gas (N₂), inert gas (e.g., helium gas (He), neon gas (Ne), argon gas (Ar)), or combinations thereof, but not limited thereto. In some embodiments, each of the first precursor gas, the second precursor gas, the etching gas, and the carrier gas has a flow rate ranging from about 10 sccm to about 200 sccm, but other ranges of values are also within the scope of this disclosure. It is noted herein that the flow rates of the first precursor gas, the second precursor gas, the etching gas and the carrier gas may be the same as or different from each other. In some embodiments, the epitaxial growth process for forming the first and second bottom portions 33, 34 are performed at a temperature ranging from about 500° C. to about 700° C. In some other embodiments, the first and second bottom portions 33, 34 may be simultaneously formed by depositing the group IV semiconductor material at the bottom regions of the source/drain recesses 30p, 30n using CVD, ALD, or other suitable deposition processes, followed by an implantation process such that the trapping elements are doped into the group IV semiconductor material.

After sub-step S121, the remaining source/drain recesses (i.e., the unfilled portions of the source/drain recesses) are denoted by 301p and 301n.

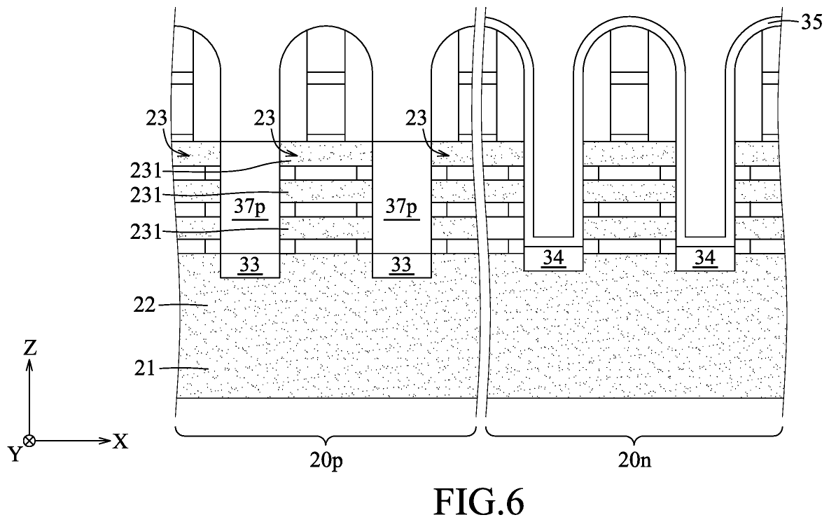

FIG. 6 is similar to FIG. 5, but illustrating the structure after sub-step S122. In sub-step S122, the first source/drain portions 37p are respectively formed on the first bottom portions 33 and respectively fill the source/drain recesses 301p (see FIG. 5).

In some embodiments, the first source/drain portions 37p may be formed by CVD, ALD, or an epitaxial growth process (such as the examples described previously). Before the epitaxial growth process of the first source/drain portions 37p, a first patterned mask layer 35 is formed to cover the structure on the n-region 20n (see FIG. 5), thereby exposing the structure on the p-region 20p (see FIG. 5). In some embodiments, the first patterned mask layer 35 may include a dielectric material (such as silicon oxide, silicon nitride, silicon oxynitride, aluminum oxide, etc.). In some embodiments, the first patterned mask layer 35 may be formed by a patterning process (for example, but not limited to, a photolithography process), and will be removed from the structure shown in FIG. 6 after formation of the first source/drain portions 37p.

FIG. 7 is similar to FIG. 6, but illustrating the structure after sub-step S123. In sub-step S123, the second source/drain portions 37n are respectively formed on the second bottom portions 34 and respectively fill the source/drain recesses 301n (see FIG. 5).

In some embodiments, the second source/drain portions 37n may be formed in a manner similar to that for forming the first source/drain portions 37p, and thus the details thereof are omitted for the sake of brevity. Before the epitaxial growth process of the second source/drain portions 37n, a second patterned mask layer 36 is formed to cover the structure on the p-region 20p (see FIG. 6), thereby exposing the structure on the n-region 20n (see FIG. 5). In some embodiments, the second patterned mask layer 36 may include a dielectric material (such as the examples set forth with respect to the first patterned mask layer 35). In some embodiments, the second patterned mask layer 36 may be formed in a manner similar to that for forming the first patterned mask layer 35, and will be removed from the structure shown in FIG. 7 after formation of the second source/drain portions 37n.

Referring to FIG. 1 and the example illustrated in FIG. 8, the method 10 proceeds to step S13, where a plurality of inter-layer dielectric portions 38 and a plurality of contact portions 39 are formed, and a gate replacement process is performed to form a plurality of gate structures 40p, 40n, thereby obtaining the semiconductor structure 50. FIG. 8 is similar to FIG. 7, but illustrating the structure after step S13. FIG. 9 is a schematic sectional view taken along line A-A′ of FIG. 8. Since the sectional view taken along line B-B′ is similar to FIG. 9, the same is omitted for the sake of brevity.

In some embodiments, each of the gate structures 40p, 40n includes a real gate dielectric layer 41 and a real gate electrode 42. Each of the gate structures 40p is formed around the first channel layers 231 of a corresponding one of the first channel portions 23, such that the first channel layers 231 of the corresponding one of the first channel portions 23 are separated from the real gate electrode 42 by the real gate dielectric layer 41, as shown in FIG. 9. Each of the gate structures 40n is formed around the second channel layers 251 of a corresponding one of the second channel portions 25, such that the second channel layers 251 of the corresponding one of the second channel portions 25 are separated from the real gate electrode 42 by the real gate dielectric layer 41.

In some embodiments, the real gate dielectric layer 41 of each of the gate structures 40p, 40n may include silicon oxide, silicon nitride, silicon oxynitride, a suitable high-k material (such as hafnium oxide, zirconium oxide, zirconium aluminum oxide, hafnium aluminum oxide, hafnium silicon oxide, aluminum oxide, etc.), other suitable materials, or combinations thereof. Other dielectric materials suitable for the real gate dielectric layer 41 are within the contemplated scope of the present disclosure.

In some embodiments, the real gate electrode 42 of each of the gate structures 40p, 40n may be configured as a multi-layered structure including (i) at least one work function metal that is provided for adjusting threshold voltage of an n-FET or a p-FET, and (ii) an electrically conductive material having a low resistance that is provided for reducing electrical resistance of the real gate electrode 42, other suitable materials, or combinations thereof. In some embodiments, the work function metal of the real gate electrode 42 for forming an n-FET may be different from that for forming a p-FET so as to permit the n-FET and the p-FET to have different threshold voltages. Other methods suitable for adjusting the threshold voltages are within the contemplated scope of the present disclosure. In some embodiments, the real gate electrode 42 may include a metal material (e.g., tungsten (W), titanium (Ti), tantalum (Ta), aluminum (Al), or ruthenium (Ru)), metal-containing nitrides (e.g., titanium nitride (TiN), or tantalum nitride (TaN)), metal-containing silicides (e.g., nickel silicide (NiSi)), metal-containing carbides (e.g., tantalum carbide (TaC)), or combinations thereof. Other suitable materials for the real gate electrode 42 are within the contemplated scope of the present disclosure. The material or configuration of the real gate electrode 42 of each gate structure 40p may be the same as or different from that of the real gate electrode 42 of each gate structure 40n.

In some embodiments, the semiconductor structure 50 further includes a plurality of cap portions 43 disposed to cover the gate structures 40p, 40n so as to protect the gate structures 40p, 40n during formation of the contact portions 39. In some embodiments, the cap portions 43 may include a dielectric material, such as silicon oxide, silicon nitride, silicon oxynitride, but not limited thereto. Other dielectric materials suitable for the cap portions 43 are within the contemplated scope of the present disclosure.

The inter-layer dielectric portions 38 are respectively formed to cover the first and second source/drain portions 37p, 37n. In some embodiments, each of the inter-layer dielectric portions 38 may include dielectric material(s) and may be formed as a single-layer structure, a bi-layered structure or a multi-layered structure. In some embodiments, possible dielectric materials suitable for the inter-layer dielectric portions 38 are similar to those for the inner spacers 29, and thus the details thereof are omitted for the sake of brevity. Other dielectric materials suitable for the inter-layer dielectric portions 38 are within the contemplated scope of the present disclosure.

The contact portions 39 are respectively formed in the inter-layer dielectric portions 38 so as to be coupled to the first and second source/drain portions 37p, 37n. In some embodiments, each of the contact portions 39 may include a conductive material, such as tungsten (W), aluminum (Al), ruthenium (Ru), cobalt (Co), copper (Cu), palladium (Pd), nickel (Ni), platinum (Pt), a low resistivity metal constituent, etc., or combinations thereof. Other conductive materials suitable for the contact portions 39 are within the contemplated scope of the present disclosure.

In some embodiments, step S13 may include (i) forming the inter-layer dielectric portions 38 to cover the first and second source/drain portions 37p, 37n by CVD, ALD or other suitable deposition processes, followed by a planarization process (such as CMP) to expose the dummy gate electrode 272 of each of the dummy gate portions 27p, 27n (see FIG. 7), (ii) performing the gate replacement process by one or more etching processes (such as dry etching, wet etching, other suitable techniques, or combinations thereof) to remove the dummy gate electrode 272 and the dummy gate dielectric layer 271 of each of the dummy gate portions 27p, 27n (see FIG. 7) to form a plurality of upper cavities (not shown) and to remove the first and second sacrificial layers 241, 261 (see FIG. 7) to form a plurality of lower cavities (not shown) respectively beneath the upper cavities, one or more deposition processes (such as CVD, ALD, PVD, or other suitable deposition processes) and one or more planarization processes (such as CMP, or other suitable planarization processes) for forming the gate structures 40p, 40n each of which is formed in one of the lower cavities and a respective one of the lower cavities, (iii) forming the cap portions 43 respectively on the gate structures 40p, 40n by CVD, ALD or other suitable deposition processes, followed by a planarization process (such as CMP), to expose the inter-layer dielectric portions 38, and (iv) forming the contact portions 39 respectively in the inter-layer dielectric portions 38 by one or more etching processes (such as dry etching, wet etching, other suitable techniques, or combinations thereof), one or more deposition processes (such as CVD, ALD, PVD, or other suitable deposition processes) and one or more planarization processes (such as CMP, or other suitable planarization processes). Other suitable process flows for obtaining the semiconductor structure 50 are within the contemplated scope of the present disclosure. In some embodiments, some steps in the method 10 may be modified, replaced, or eliminated without departure from the spirit and scope of the present disclosure. In some alternative embodiments, the semiconductor structure 50 may further include additional features, and/or some features present in the semiconductor structure 50 may be modified, replaced, or eliminated without departure from the spirit and scope of the present disclosure.

As shown in FIG. 8, the p-FET 51p includes one of the first channel portions 23 (e.g., a center one of the first channel portions 23 shown in FIG. 8), two corresponding adjacent ones of the first source/drain portions 37p disposed at two opposite sides of the one of the first channel portions 23 in the X direction, two corresponding ones of the first bottom portions 33 respectively disposed beneath the two corresponding adjacent ones of the first source/drain portions 27p, a corresponding one of the gate structures 40p disposed around the first channel layers 231 of the one of the first channel portions 23, and two corresponding ones of the contact portions 39 coupled to the two corresponding adjacent ones of the first source/drain portions 37p. As such, a current flow flowing through the first channel layers 231 of the first channel portion 23 of the p-FET 51p may be controlled by an external circuit or an external controller through the corresponding gate structure 40p and the two corresponding contact portions 39. Also, the n-FET 51n includes one of the second channel portions 25 (e.g., a center one of the second channel portions 25 shown in FIG. 8), two corresponding adjacent ones of the second source/drain portions 37n disposed at two opposite sides of the one of the second channel portions 25 in the X direction, two corresponding ones of the second bottom portions 34 respectively disposed beneath the two corresponding adjacent ones of the second source/drain portions 37n, a corresponding one of the gate structures 40n disposed around the second channel layers 251 of the one of the second channel portions 25, and two corresponding ones of the contact portions 39 coupled to the two corresponding adjacent ones of the second source/drain portions 27n. As such, a current flow flowing through the second channel layers 251 of the second channel portion 25 of the n-FET 51n may be controlled by an external circuit or an external controller through the corresponding gate structure 40n and the two corresponding contact portions 39.

It is worth noting that with provision of the first and second bottom portions 33, 34 in this disclosure, the p-type dopant in the first source/drain portions 37p diffusing toward the p-region 20p of the fin portion 22 during subsequent thermal processes will be trapped by the trapping elements in the first bottom portions 33, and the n-type dopant in the second source/drain portions 37n diffusing toward the n-region 20n of the fin portion 22 during subsequent thermal processes will be trapped by the trapping elements in the second bottom portions 34. Therefore, a substrate leakage current flowing from each of the first and second source/drain portions 37p, 37n to the substrate 21 may be suppressed. Furthermore, since each of the first and second bottom portions 33, 34 includes the group IV semiconductor material and the trapping elements doped in the group IV semiconductor material, rather than a dielectric material, each of the first and second source/drain portions 37p, 37n may be well epitaxially grown thereon without voids being formed in the first and second source/drain portions 37p, 37n. Accordingly, the electrical performance of each of the p-FET 50p and the n-FET 50n in this disclosure is significantly improved due to suppressed substrate leakage current and less defects.

In accordance with some embodiments of the present disclosure, a method for manufacturing a semiconductor structure includes: forming a channel portion on a fin portion; forming two source/drain portions on the fin portion and at two opposite sides of the channel portion, in which each of the two source/drain portions includes a first semiconductor material that is doped with dopant impurities; and forming two bottom portions each of which is disposed between the fin portion and a corresponding one of the two source/drain portions, in which each of the two bottom portions includes a second semiconductor material that is different from the first semiconductor material and that is capable of trapping the dopant impurities when the dopant impurities in the first semiconductor material diffuse toward the fin portion.

In accordance with some embodiments of the present disclosure, the two source/drain portions are spaced apart from each other in an X direction, the channel portion includes a plurality of channel layers spaced apart from each other in a Z direction transverse to the X direction, and a bottommost one of the channel layers is spaced apart from the fin portion in the Z direction.

In accordance with some embodiments of the present disclosure, each of the two bottom portions is separated from the channel layers through the corresponding one of the two source/drain portions, and the two source/drain portions are entirely separated from the fin portion.

In accordance with some embodiments of the present disclosure, each of the two bottom portions has an upper surface at a level lower than that of a lower surface of the bottommost one of the channel layers.

In accordance with some embodiments of the present disclosure, the method further includes forming a gate structure around the channel layers, and forming a plurality of pairs of inner spacers that are disposed to separate the gate structure from the two source/drain portions, in which the two inner spacers in a bottommost pair of the inner spacers are covered by the two bottom portions, respectively.

In accordance with some embodiments of the present disclosure, each of the two bottom portions has a thickness ranging from 0.5 nm to 10 nm.

In accordance with some embodiments of the present disclosure, the first semiconductor material includes a group IV element and the dopant impurities doped in the group IV element, the dopant impurities including a group III element or a group V element.

In accordance with some embodiments of the present disclosure, the second semiconductor material is silicon doped with carbon, antimony, gallium, or combinations thereof.

In accordance with some embodiments of the present disclosure, a method for manufacturing a semiconductor structure includes: forming a fin portion having a p-region and an n-region displaced from the p-region; forming a first device on the p-region of the fin portion, in which the first device includes a first channel portion, two first source/drain portions including a p-type semiconductor material that is doped with a p-type dopant, and two first bottom portions each of which is disposed between the fin portion and a corresponding one of the two first source/drain portions, and each of which is capable of trapping the p-type dopant when the p-type dopant in the corresponding one of the two first source/drain portions diffuses toward the fin portion; and forming a second device on the n-region of the fin portion, in which the second device includes a second channel portion, two second source/drain portions including an n-type semiconductor material that is doped with an n-type dopant, and two second bottom portions each of which is disposed between the fin portion and a corresponding one of the two second source/drain portions, and each of which is capable of trapping the n-type dopant when the n-type dopant in the corresponding one of the two second source/drain portions diffuses toward the fin portion.

In accordance with some embodiments of the present disclosure, the two first bottom portions and the two second bottom portions are made of a same material.

In accordance with some embodiments of the present disclosure, each of the two first bottom portions and the two second bottom portions includes a group IV semiconductor material and trapping elements doped in the group IV semiconductor material, the trapping elements including carbon, antimony, gallium, or combinations thereof.

In accordance with some embodiments of the present disclosure, the trapping elements are in an atomic percentage ranging from 0.02% to 10% based on total atoms of the group IV semiconductor material and the trapping elements.

In accordance with some embodiments of the present disclosure, the first channel portion and the second channel portion are simultaneously formed, and the two first bottom portions and the two second bottom portions are simultaneously formed before forming the two first source/drain portions and the two second source/drain portions.

In accordance with some embodiments of the present disclosure, each of the two first bottom portions and the two second bottom portions has a thickness ranging from 0.5 nm to 10 nm.

In accordance with some embodiments of the present disclosure, the two first source/drain portions are disposed at two opposite sides of the first channel portion in an X direction, the two second source/drain portions are disposed at two opposite sides of the second channel portion in the X direction, and each of the first channel portion and the second channel portion includes a plurality of channel layers spaced apart from each other in a Z direction transverse to the X direction.

In accordance with some embodiments of the present disclosure, each of the two first bottom portions is separated from the channel layers of the first channel portion through the corresponding one of the two first source/drain portions, and each of the two second bottom portions is separated from the channel layers of the second channel portion through the corresponding one of the two second source/drain portions.

In accordance with some embodiments of the present disclosure, a semiconductor structure, includes: a channel portion disposed on a fin portion; two source/drain portions disposed on the fin portion and respectively at two opposite sides of the channel portion; and two bottom portions each of which is disposed between the fin portion and a corresponding one of the two source/drain portions. Each of the two source/drain portions includes a first semiconductor material that is doped with dopant impurities, and each of the two bottom portions includes a second semiconductor material that is different from the first semiconductor material and that is capable of trapping the dopant impurities when the dopant impurities in the first semiconductor material diffuse toward the fin portion.

In accordance with some embodiments of the present disclosure, the two source/drain portions are spaced apart from each other by the channel portion in an X direction, the channel portion includes a plurality of channel layers spaced apart from each other in a Z direction transverse to the X direction, and a bottommost one of the channel layers is spaced apart from the fin portion in the Z direction.

In accordance with some embodiments of the present disclosure, each of the two bottom portions is separated from the channel layers through the corresponding one of the two source/drain portions.

In accordance with some embodiments of the present disclosure, the first semiconductor material includes a group IV element and the dopant impurities doped in the group IV element, the dopant impurities include a group III element or a group V element, and the second semiconductor material includes a group IV element doped with doped with carbon, antimony, gallium, or combinations thereof.

In accordance with some embodiments of the present disclosure, a method for manufacturing a semiconductor structure includes: forming two channel portions and a source/drain recess between the two channel portions, in which the two channel portions are formed on a fin portion and are formed to be spaced apart from each other; forming a source/drain portion in the source/drain recess such that the source/drain portion is disposed between and in contact with the two channel portions, in which the source/drain portion includes a first semiconductor material that is doped with dopant impurities; and forming a bottom portion in the source/drain recess and beneath the source/drain portion, in which the bottom portion includes a second semiconductor material that is different from the first semiconductor material and which is capable of trapping the dopant impurities when the dopant impurities in the first semiconductor material diffuse toward the fin portion.

In accordance with some embodiments of the present disclosure, the second semiconductor material is silicon doped with carbon, antimony, gallium, or combinations thereof.

In accordance with some embodiments of the present disclosure, the two channel portions are spaced apart from each other in an X direction, each of the two channel portions includes a plurality of channel layers spaced apart from each other in a Z direction transverse to the X direction, a bottommost one of the channel layers in each of the channel portions is spaced apart from the fin portion in the Z direction, and the bottom portion is separated from each of the channel layers of the two channel portions through the source/drain portion.

In accordance with some embodiments of the present disclosure, the bottom portion is formed to entirely separate the source/drain portion from the fin portion.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a channel portion on a fin portion;
forming two source/drain portions on the fin portion and at two opposite sides of the channel portion, each of the two source/drain portions including a first semiconductor material that is doped with dopant impurities; and
forming two bottom portions each of which is disposed between the fin portion and a corresponding one of the two source/drain portions, each of the two bottom portions including a second semiconductor material that is different from the first semiconductor material and that is capable of trapping the dopant impurities when the dopant impurities in the first semiconductor material diffuse toward the fin portion.

2. The method as claimed in claim 1, wherein the two source/drain portions are spaced apart from each other in an X direction, the channel portion including a plurality of channel layers spaced apart from each other in a Z direction transverse to the X direction, a bottommost one of the channel layers being spaced apart from the fin portion in the Z direction.

3. The method as claimed in claim 2, wherein:
each of the two bottom portions is separated from the channel layers through the corresponding one of the two source/drain portions; and
the two source/drain portions are entirely separated from the fin portion.

4. The method as claimed in claim 2, wherein each of the two bottom portions has an upper surface at a level lower than that of a lower surface of the bottommost one of the channel layers.

5. The method as claimed in claim 2, further comprising:
forming a gate structure around the channel layers; and
forming a plurality of pairs of inner spacers that are disposed to separate the gate structure from the two source/drain portions, the two inner spacers in a bottommost pair of the inner spacers being covered by the two bottom portions, respectively.

6. The method as claimed in claim 2, wherein each of the two bottom portions has a thickness ranging from 0.5 nm to 10 nm.

7. The method as claimed in claim 1, wherein the first semiconductor material includes a group IV element and the dopant impurities doped in the group IV element, the dopant impurities including a group III element or a group V element.

8. The method as claimed in claim 1, wherein the second semiconductor material is silicon doped with carbon, antimony, gallium, or combinations thereof.

9. A method for manufacturing a semiconductor structure, comprising:
forming a fin portion having a p-region and an n-region displaced from the p-region;
forming a first device on the p-region of the fin portion, the first device including
a first channel portion,
two first source/drain portions including a p-type semiconductor material that is doped with a p-type dopant, and
two first bottom portions each of which is disposed between the fin portion and a corresponding one of the two first source/drain portions, and each of which is capable of trapping the p-type dopant when the p-type dopant in the corresponding one of the two first source/drain portions diffuses toward the fin portion; and
forming a second device on the n-region of the fin portion, the second device including
a second channel portion,
two second source/drain portions including an n-type semiconductor material that is doped with an n-type dopant, and
two second bottom portions each of which is disposed between the fin portion and a corresponding one of the two second source/drain portions, and each of which is capable of trapping the n-type dopant when the n-type dopant in the corresponding one of the two second source/drain portions diffuses toward the fin portion.

10. The method as claimed in claim 9, wherein the two first bottom portions and the two second bottom portions are made of a same material.

11. The method as claimed in claim 9, wherein each of the two first bottom portions and the two second bottom portions includes a group IV semiconductor material and trapping elements doped in the group IV semiconductor material, the trapping elements including carbon, antimony, gallium, or combinations thereof.

12. The method as claim in claim 11, wherein the trapping elements are in an atomic percentage ranging from 0.02% to 10% based on total atoms of the group IV semiconductor material and the trapping elements.

13. The method as claimed in claim 9, wherein the first channel portion and the second channel portion are simultaneously formed, the two first bottom portions and the two second bottom portions being simultaneously formed before forming the two first source/drain portions and the two second source/drain portions.

14. The method as claimed in claim 9, wherein each of the two first bottom portions and the two second bottom portions has a thickness ranging from 0.5 nm to 10 nm.

15. The method as claim in claim 9, wherein the two first source/drain portions are disposed at two opposite sides of the first channel portion in an X direction, the two second source/drain portions being disposed at two opposite sides of the second channel portion in the X direction, each of the first channel portion and the second channel portion including a plurality of channel layers spaced apart from each other in a Z direction transverse to the X direction.

16. The method as claimed in claim 15, wherein each of the two first bottom portions is separated from the channel layers of the first channel portion through the corresponding one of the two first source/drain portions, each of the two second bottom portions being separated from the channel layers of the second channel portion through the corresponding one of the two second source/drain portions.

17. A semiconductor structure, comprising:
a channel portion disposed on a fin portion;
two source/drain portions disposed on the fin portion and respectively at two opposite sides of the channel portion, each of the two source/drain portions including a first semiconductor material that is doped with dopant impurities; and
two bottom portions each of which is disposed between the fin portion and a corresponding one of the two source/drain portions, each of the two bottom portions including a second semiconductor material that is different from the first semiconductor material and that is capable of trapping the dopant impurities when the dopant impurities in the first semiconductor material diffuse toward the fin portion.

18. The semiconductor structure as claimed in claim 17, wherein the two source/drain portions are spaced apart from each other by the channel portion in an X direction, the channel portion including a plurality of channel layers spaced apart from each other in a Z direction transverse to the X direction, a bottommost one of the channel layers being spaced apart from the fin portion in the Z direction.

19. The semiconductor structure as claimed in claim 18, wherein each of the two bottom portions is separated from the channel layers through the corresponding one of the two source/drain portions.

20. The semiconductor structure as claimed in claim 17, wherein the first semiconductor material includes a group IV element and the dopant impurities doped in the group IV element, the dopant impurities including a group III element or a group V element, the second semiconductor material including a group IV element doped with doped with carbon, antimony, gallium, or combinations thereof.
